(19) United States
(12) Patent Application Publication
(10) Pub. No.: US 2007/0272947 A1
(43) Pub. Date: Nov. 29, 2007

(54) Low Power Consuming Semiconductor Device

(76) Inventors: Jeng-Huang Wu, Taipei City (TW); Shang-Chih Hsieh, Kao-Hsiung Hsien (TW); Yu-Wen Tsai, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/382,487

(22) Filed: May 10, 2006

(51) Int. Cl. H01L 27/10

(52) U.S. Cl. 257/202

(57) ABSTRACT

A low power consuming semiconductor device comprises a p substrate, a first semiconductor cell formed over the p substrate, a second semiconductor cell formed over the p substrate adjacent to the first semiconductor cell, and a tap cell for coupling a power pin to n-well structures of the first semiconductor cell and the second semiconductor cell, and for coupling a ground pin to the p substrate. A total height of the first semiconductor cell and the second semiconductor cell is twice a height of a standard semiconductor cell, and the height of the second semiconductor cell is adjusted according to the height of the first semiconductor cell.

### BACKGROUND OF THE INVENTION

1. Field of the Invention

The present invention provides a semiconductor device, and more particularly, a semiconductor device capable decreasing leakage power in sleep mode.

2. Description of the Prior Art

In order to design circuits more efficiently, logic cell libraries composed of common-use logic circuits are used in the prior art. According to different requirements, a designer must select adaptive logic cell libraries to synthesize logic circuits. The prior art has provided layouts for high-efficiency, high-density, and low-power operations. However, the low-power layouts are aimed at requirements of low active power, but not that of low power leakage, which must be considered in advanced processes, such as deep sub-micron applications.

Please refer to FIG. 1, which illustrates a schematic diagram of a high-density semiconductor layout 10 in accordance with the prior art. The semiconductor layout 10 is utilized for implementing four common transmission gates, and includes a first semiconductor cell 100 and a second semiconductor cell 102. The first semiconductor cell 100 includes a first n diffusion region 104, a second n diffusion region 106, a first p diffusion region 108, a second p diffusion region 110, a first poly-silicon conductor 112, a second poly-silicon conductor 114, a third poly-silicon conductor 116, and a fourth poly-silicon conductor 118. Both the first poly-silicon conductor 112 and the second poly-silicon conductor 114 extend from the first n diffusion region 104 to the second n diffusion region 106, and bisect the first n diffusion region 104 and the second n diffusion region 106 to form four n MOS transistors. Similarly, both the third poly-silicon conductor 116 and the fourth poly-silicon conductor 118 extend from the first p diffusion region 108 to the second p diffusion region 110, and bisect the first p diffusion region 108 and the second p diffusion region 110 to form four p MOS transistors. The second semiconductor cell 102 includes a first clock output pin 120 and a second clock output pin 122 for outputting clock signals. The semiconductor layout 10 further includes a fifth poly-silicon conductor 124 and a sixth poly-silicon conductor 126. The fifth poly-silicon conductor 124 extends from the first clock output pin 120 to the first poly-silicon conductor 112 and the fourth poly-silicon conductor 118, and the sixth poly-silicon conductor 126 extends from the second clock output pin 122 to the second poly-silicon conductor 114 and the third poly-silicon conductor 116. When compressing the semiconductor layout 10, a height H2 of the second semiconductor cell 102 is adjusted based on a height H1 of the first semiconductor cell 100. That is, if the first semiconductor cell 100 cannot be compressed to half the height of the semiconductor layout 10, a designer can reduce the height H2 of the second semiconductor cell 102, so as to lay the first semiconductor cell 100 and the second semiconductor cell 102 within the required height, and construct a high-density cell library.

The semiconductor layout 10 can implement high-efficiency and high-density common pass gates. However, potentials of n-well structures and a p substrate of the semiconductor layout 10 are coupled to pins through a standard semiconductor cell. As a result, when operating in sleep mode, the semiconductor layout 10 will generate power leakage, which increases power consumption, and wastes system resources.

### SUMMARY OF THE INVENTION

It is therefore a primary objective of the claimed invention to provide low power consuming semiconductor devices.

An exemplary embodiment of a low power consuming semiconductor device comprises a p substrate, a first semiconductor cell, a second semiconductor cell, and a tap cell. The first semiconductor cell is formed over the p substrate. The second semiconductor cell is formed over the p substrate adjacent to the first semiconductor cell. A total height of the first semiconductor cell and the second semiconductor cell is twice a height of a standard semiconductor cell, and the height of the second semiconductor cell is adjusted according to the height of the first semiconductor cell. The tap cell is utilized for coupling a power pin to n-well structures of the first semiconductor cell and the second semiconductor cell, and for coupling a ground pin to the p substrate.

An exemplary embodiment of a low power consuming semiconductor device comprises a p substrate, a first semiconductor cell, a second semiconductor cell, and a tap cell. The first semiconductor cell is formed over the p substrate. The second semiconductor cell is formed over the p substrate adjacent to the first semiconductor cell. A total height of the first semiconductor cell and the second semiconductor cell is twice a height of a standard semiconductor cell, and the height of the second semiconductor cell is adjusted according to the height of the first semiconductor cell. The tap cell is utilized for coupling n-well structures of the first semiconductor cell and the second semiconductor cell to pins different from pins coupled to a power pin, and for coupling a ground pin to the p substrate.

An exemplary embodiment of a low power consuming semiconductor device comprises a p substrate, a first semiconductor cell, a second semiconductor cell, and a tap cell. The first semiconductor cell is formed over the p substrate. The second semiconductor cell is formed over the p substrate adjacent to the first semiconductor cell. A total height of the first semiconductor cell and the second semiconductor cell is twice a height of a standard semiconductor cell, and the height of the second semiconductor cell is adjusted according to the height of the first semiconductor cell. The tap cell is utilized for coupling a power pin to n-well structures of the first semiconductor cell and the second semiconductor cell, and coupling the p substrate to pins different from pins coupled to a ground pin.

An exemplary embodiment of a low power consuming semiconductor device comprises a p substrate, a first semiconductor cell, a second semiconductor cell, and a tap cell. The first semiconductor cell is formed over the p substrate. The second semiconductor cell is formed over the p substrate adjacent to the first semiconductor cell. A total height of the first semiconductor cell and the second semiconductor cell is twice a height of a standard semiconductor cell, and the height of the second semiconductor cell is adjusted according to the height of the first semiconductor cell. The tap cell is utilized for coupling n-well structures of the first semiconductor cell and the second semiconductor cell to pins different from pins coupled to a power pin, and coupling the p substrate to pins different from pins coupled to a ground pin.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a high-efficiency semiconductor layout in accordance with the prior art.

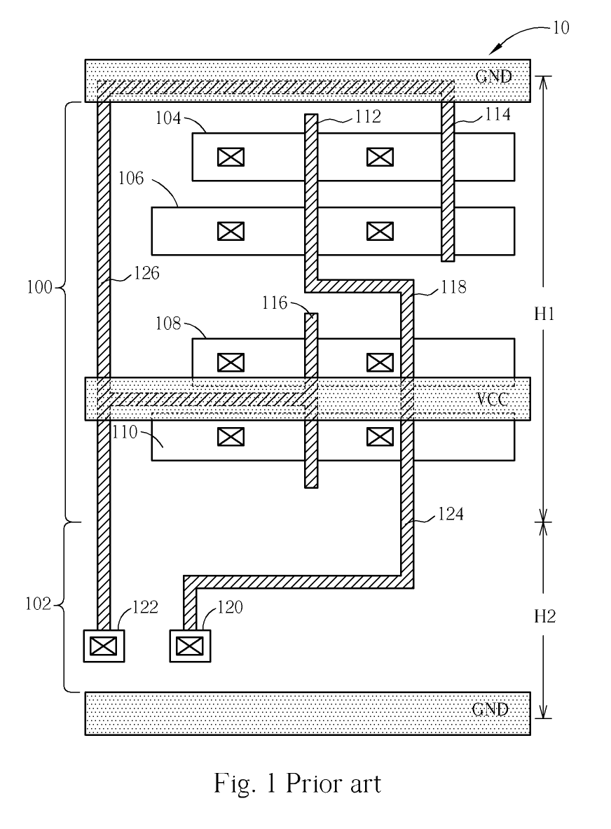

FIG. 2 illustrates a schematic diagram of a low power consuming semiconductor device in accordance with the present invention.

### DETAILED DESCRIPTION

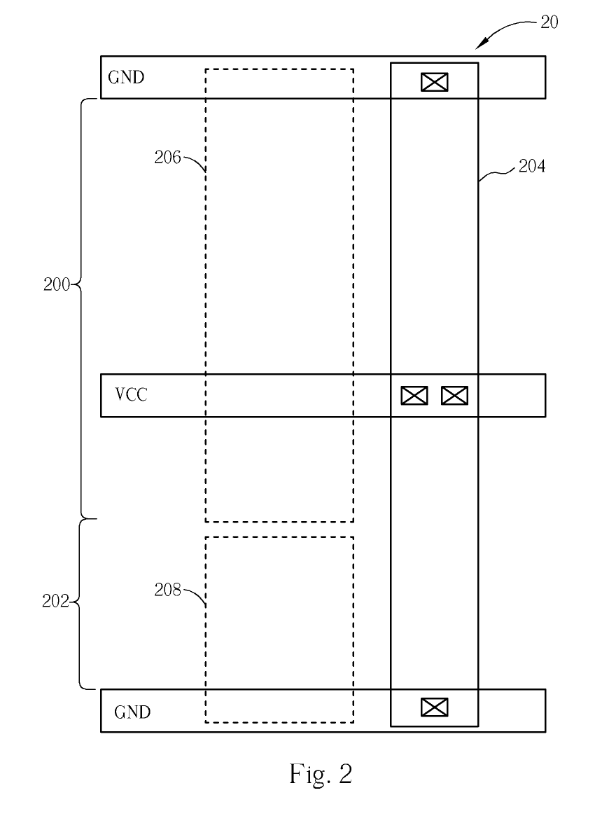

Please refer to FIG. 2, which illustrates a schematic diagram of a low power consuming semiconductor device 20 in accordance with the present invention. The semiconductor device 20 includes a first semiconductor cell 200, a second semiconductor cell 202, and a tap cell 204 on a p substrate (not shown in FIG. 2). The first semiconductor cell 200 and the second semiconductor cell 202 include transistor units 206 and 208, which are preferably formed by a COMS process. A total height of the first semiconductor cell 200 and the second semiconductor cell 202 is twice a height of a standard semiconductor cell, and a height of the second semiconductor cell 202 is adjusted based on a height of the first semiconductor cell 200. That is, if the first semiconductor cell 200 cannot be compressed to half the total height, a designer can reduce the height of the second semiconductor cell 202, so as to lay the first semiconductor cell 200 and the second semiconductor cell 202 within the required height. The tap cell 204 is utilized for providing power and ground potentials to n-well structures and the p substrate in the first semiconductor cell 200 and the second semiconductor cell 202. That is, the n-well structures and the p substrate are not coupled to pins through a standard semiconductor cell. Therefore, when the semiconductor device 20 operates in sleep mode, the tap cell 204 can decrease power leakage by setting different bias voltages to the n-well structures and the p substrate.

According to different applications, the tap cell 204 can apply the following bias settings to decrease power leakage:

1. The tap cell 204 couples a power pin to the n-well structures, and couples a ground pin to the p substrate.

2. The tap cell 204 does not couple a power pin to the n-well structures, but couples a ground pin to the p substrate. That is, the power pin and the n-well structures are coupled to different pins.

3. The tap cell 204 couples a power pin to the n-well structures, but does not couple a ground pin to the p substrate. That is, the ground pin and the p substrate are coupled to different pins.

4. The tap cell 204 does not couple a power pin to the n-well structures, and does not couple a ground pin to the p substrate. That is, the power pin and the n-well structures are coupled to different pins, and the ground pin and the p substrate are coupled to different pins.

In summary, the height of the second semiconductor cell 202 is adjusted according to the height of the first semiconductor cell 200, so as to increase layout density of the semiconductor device 20 to decrease power consumption. In addition, potentials of the p substrate and the n-well structures in the semiconductor device 20 are not coupled to pins through the first semiconductor cell 200 and the second semiconductor cell 202, but through the tap cell 204, so as to decrease power leakage in the sleep mode by applying the above bias settings. Therefore, the present invention semiconductor device 20 can decrease power consumption and power leakage in the sleep mode.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A low power consuming semiconductor device comprising:
a p substrate;
a first semiconductor cell formed over the p substrate;
a second semiconductor cell formed over the p substrate adjacent to the first semiconductor cell, wherein a total height of the first semiconductor cell and the second semiconductor cell is twice a height of a standard semiconductor cell, and the height of the second semiconductor cell is adjusted according to the height of the first semiconductor cell; and
a tap cell for coupling a power pin to n-well structures of the first semiconductor cell and the second semiconductor cell, and for coupling a ground pin to the p substrate.

2. The low power consuming semiconductor device of claim 1, wherein the height of the standard semiconductor cell is 6, 7, 8, or 9 grids.

3. A low power consuming semiconductor device comprising:
a p substrate;
a first semiconductor cell formed over the p substrate;
a second semiconductor cell formed over the p substrate adjacent to the first semiconductor cell, wherein a total height of the first semiconductor cell and the second semiconductor cell is twice a height of a standard semiconductor cell, and the height of the second semiconductor cell is adjusted according to the height of the first semiconductor cell; and
a tap cell for coupling n-well structures of the first semiconductor cell and the second semiconductor cell to pins different from pins coupled to a power pin, and for coupling a ground pin to the p substrate.

4. The low power consuming semiconductor device of claim 3, wherein the height of the standard semiconductor cell is 6, 7, 8, or 9 grids.

5. A low power consuming semiconductor device comprising:
a p substrate;
a first semiconductor cell formed over the p substrate;
a second semiconductor cell formed over the p substrate adjacent to the first semiconductor cell, wherein a total height of the first semiconductor cell and the second semiconductor cell is twice a height of a standard semiconductor cell, and the height of the second semiconductor cell is adjusted according to the height of the first semiconductor cell; and
a tap cell for coupling a power pin to n-well structures of the first semiconductor cell and the second semiconductor cell, and coupling the p substrate to pins different from pins coupled to a ground pin.

6. The low power consuming semiconductor device of claim 5, wherein the height of the standard semiconductor cell is 6, 7, 8, or 9 grids.

7. A low power consuming semiconductor device comprising:
a p substrate;
a first semiconductor cell formed over the p substrate;
a second semiconductor cell formed over the p substrate adjacent to the first semiconductor cell, wherein a total height of the first semiconductor cell and the second semiconductor cell is twice a height of a standard semiconductor cell, and the height of the second semiconductor cell is adjusted according to the height of the first semiconductor cell; and
a tap cell for coupling n-well structures of the first semiconductor cell and the second semiconductor cell to pins different from pins coupled to a power pin, and coupling the p substrate to pins different from pins coupled to a ground pin.

8. The low power consuming semiconductor device of claim 7, wherein the height of the standard semiconductor cell is 6, 7, 8, or 9 grids.
